(19) United States
(12) Patent Application Publication
(10) Pub. No.: US 2015/0077524 A1
(43) Pub. Date: Mar. 19, 2015

(54) IMAGE SENSOR AND IMAGING DEVICE

(71) Applicant: NIKON CORPORATION, Tokyo (JP)

(72) Inventor: Satoshi SUZUKI, Tokyo (JP)

(21) Appl. No.: 14/476,367

(22) Filed: Sep. 3, 2014

Related U.S. Application Data
(63) Continuation of application No. PCT/JP2013/001812, filed on Mar. 15, 2013.

(30) Foreign Application Priority Data
Mar. 16, 2012 (JP) 2012-060753

(51) Int. Cl. H01L 27/146; H04N 13/02

(52) U.S. Cl. CPC H01L 27/1463; H01L 27/14621; H01L 27/14685; H04N 13/0282
USPC 348/49; 257/432; 438/73

(57) ABSTRACT

In a conventional imaging device, a light-blocking member for blocking incident luminous fluxes is provided for each pixel, for generating a parallax image. However, the light-blocking member is provided apart from the photoelectric converter element, and so unnecessary light such as diffracted light generated at the boundary between the light-blocking member and the aperture portion sometimes reaches the photoelectric converter element. In view of this, provided is an imaging sensor including: photoelectric converter elements aligned two dimensionally, and photoelectric converting incident light into an electric signal; and reflection rate adjusted films, each of which is formed on a light receiving surface of a photoelectric converter element of at least a part of the photoelectric converter elements and at least includes a first portion having a first reflection rate and a second portion having a second reflection rate different from the first reflection rate.

### BACKGROUND

1. Technical Field

The present invention relates to an image sensor and an imaging device.

2. Related Art

An imaging device which captures two parallax images having parallax at one imaging using a single image-capturing optical system has been known.

### PRIOR ART DOCUMENT

Patent Document 1: Japanese Patent Application Publication No. 2003-7994

In the above-mentioned imaging device, a light-blocking member for blocking incident luminous fluxes is provided for each pixel, for generating a parallax image. However, the light-blocking member is provided apart from the photoelectric converter element, and so unnecessary light such as diffracted light generated at the boundary between the light-blocking member and the aperture portion sometimes reaches the photoelectric converter element.

### SUMMARY

A first aspect of the innovations may include an image sensor including: photoelectric converter elements aligned two dimensionally, and photoelectric converting incident light into an electric signal; and reflection rate adjusted films, each of which is formed on a light receiving surface of a photoelectric converter element of at least a part of the photoelectric converter elements and at least includes a first portion having a first reflection rate and a second portion having a second reflection rate different from the first reflection rate.

A second aspect of the innovations may include imaging device, including: the image sensor described above; and an image processor that generates, from an output of the image sensor, a plurality of pieces of parallax image data having parallax to each other and 2D no-parallax image data.

A third aspect of the innovations may include a method of manufacturing reflection rate adjusted films formed on light receiving surfaces of photoelectric converter elements aligned two dimensionally and photoelectric converting incident light into an electric signal, the method including: depositing a first film on a substrate on which the photoelectric converter elements are formed; adjusting a film thickness of the first film so that a first portion and a second portion resulting from dividing a light receiving surface of each of the photoelectric converter elements have film thicknesses different from each other; depositing a second film different from the first film, on the first film; and adjusting a film thickness of the second film so that the first portion and the second portion have film thicknesses different from each other.

A fourth aspect of the innovations may include a method of manufacturing reflection rate adjusted films formed on light receiving surfaces of photoelectric converter elements aligned two dimensionally and photoelectric converting incident light into an electric signal, the method including: depositing a first film on a substrate on which the photoelectric converter elements are formed; masking a first portion, out of the first portion and a second portion resulting from dividing a light receiving surface of each of the photoelectric converter elements; etching the first film; depositing a second film different from the first film, on the first film; masking one of the first portion and the second portion; and etching the second film.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 explains a configuration of a digital camera according to the present embodiment.

FIG. 2 is an overview showing a cross section of an image sensor according to the present embodiment.

FIG. 3A explains a configuration of a reflection rate adjusted film according to the present embodiment.

FIG. 3B explains a configuration of a reflection rate adjusted film according to the present embodiment.

FIG. 4 is an overview showing an enlarged view of a part of an image sensor.

FIGS. 5A-5C are conceptual diagrams explaining the relation between a parallax pixel and a subject.

FIG. 6 is a conceptual diagram explaining a process of generating a parallax image.

FIG. 7 explains a Bayer array.

FIG. 8 explains an array of a repeating pattern 110 in a first embodiment example.

FIG. 9 explains an array of a repeating pattern 110 in a second embodiment example.

FIG. 10 explains an example of a generation process of RGB plane data as 2D image data.

FIG. 11 explains an example of a generation process of two pieces of G plane data as parallax image data.

FIG. 12 explains an example of a generation process of two pieces of B plane data as parallax image data.

FIG. 13 explains an example of a generation process of two pieces of R plane data as parallax image data.

FIG. 14 is a conceptual diagram showing the relation of resolutions of respective planes.

FIG. 15 explains a shape of a first portion 106.

FIG. 16 schematically shows a cross section of an image sensor according to a first modification example.

FIG. 17 schematically shows a cross section of an image sensor according to a second modification example.

FIG. 18A and FIG. 18B explain a configuration of a reflection rate adjusted film adjusted to the incident light characteristic.

FIG. 19A and FIG. 19B explain a configuration of a reflection rate adjusted film according to another variation.

FIG. 20 shows a process flow according to a first manufacturing process.

FIG. 21 shows a process flow according to a second manufacturing process.

FIG. 22 shows a simulation result of a reflection rate of each film composition with respect to an incident wavelength.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

A digital camera relating to the present embodiment, which is a form of an image processing apparatus and an imaging device, is configured to be able to produce a plurality of images of a plurality of viewpoints for a single scene, with a single image-capturing operation. Here, the images from different viewpoints are referred to as parallax images.

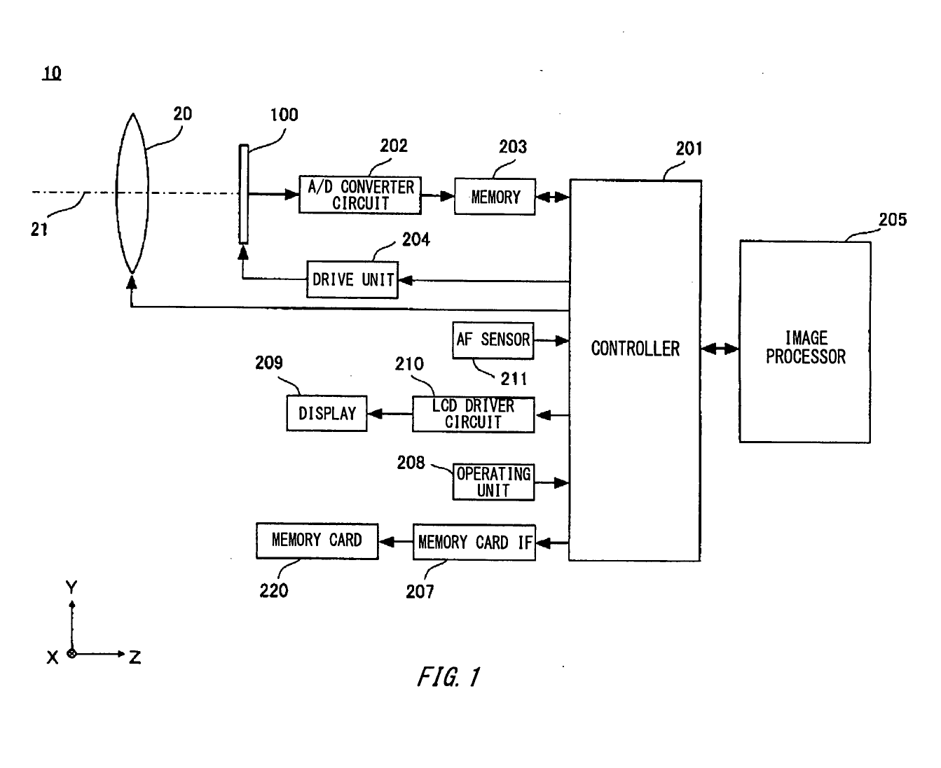

FIG. 1 illustrates the configuration of a digital camera 10 according to the present embodiment. The digital camera 10 includes an image-capturing lens 20, which is an image-capturing optical system, and guides incoming subject luminous flux along an optical axis 21 to an image sensor 100. The image-capturing lens 20 may be a replaceable lens that is attachable and detachable to/from the digital camera 10. The digital camera 10 includes the image sensor 100, a controller 201, an A/D converter circuit 202, a memory 203, a drive unit 204, an image processor 205, a memory card IF 207, an operating unit 208, a display 209, an LCD drive circuit 210, and an AF sensor 211.

As shown in FIG. 1, a z-axis positive direction is defined as the direction parallel to the optical axis 21 toward the image sensor 100, an x-axis positive direction is defined as the direction toward the viewer of the sheet of FIG. 1 in the plane orthogonal to the z axis, and a y-axis positive direction is defined as the upward direction in the sheet of FIG. 1. In some of the following drawings, their coordinate axes show how the respective drawings are arranged relative to the coordinate axes of FIG. 1.

The image-capturing lens 20 is constituted by a group of optical lenses and configured to form an image from the subject luminous flux from a scene in the vicinity of its focal plane. For the convenience of description, the image-capturing lens 20 is hypothetically represented by a single lens positioned in the vicinity of the pupil in FIG. 1. The image sensor 100 is positioned in the vicinity of the focal plane of the image-capturing lens 20. The image sensor 100 is an image sensor having a two-dimensionally arranged photoelectric converter elements, for example, a CCD or CMOS sensor. The timing of the image sensor 100 is controlled by the drive unit 204 so that the image sensor 100 can convert a subject image formed on the light receiving surface into an image signal and outputs the image signal to the A/D converter circuit 202.

The A/D converter circuit 202 converts the image signal output from the image sensor 100 into a digital image signal and outputs the digital image signal to the memory 203. The image processor 205 uses the memory 203 as its workspace to perform a various image processing operations and thus generates image data.

The image processor 205 additionally performs general image processing operations such as adjusting image data in accordance with a selected image format. The produced image data is converted by the LCD drive circuit 210 into a display signal and displayed on the display 209. In addition, the produced image data is stored in the memory card 220 attached to the memory card IF 207.

The AF sensor 211 is a phase detection sensor having a plurality of ranging points set in a subject space and configured to detect a defocus amount of a subject image for each ranging point. A series of image-capturing sequences is initiated when the operating unit 208 receives a user operation and outputs an operating signal to the controller 201. The various operations such as AF and AE associated with the image-capturing sequences are performed under the control of the controller 201. For example, the controller 201 analyzes the detection signal from the AF sensor 211 to perform focus control to move a focus lens that constitutes a part of the image-capturing lens 20.

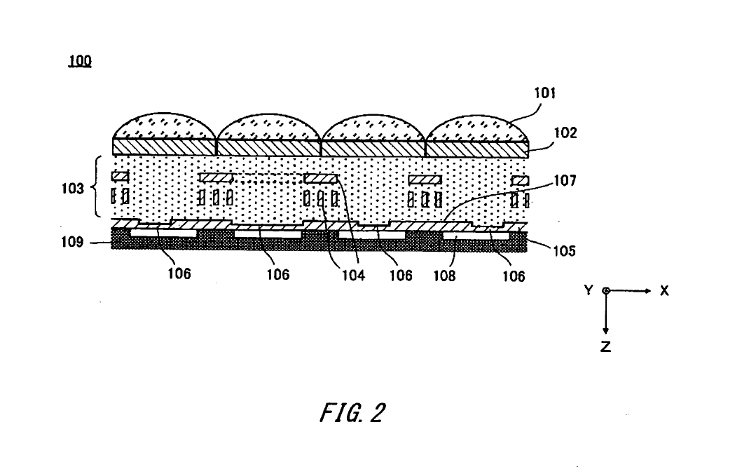

The following describes the configuration of the image sensor 100 in detail. FIG. 2 schematically illustrates the cross-section of the image sensor 100 relating to the present embodiment.

The image sensor 100 is structured in such a manner that microlenses 101, color filters 102, interconnection layer 103, an reflection rate adjusted film 105 and photoelectric converter elements 108 are arranged in the stated order when seen from the side facing a subject. The photoelectric converter elements 108 are formed by photodiodes that may convert incoming light into an electrical signal. The photoelectric converter elements 108 are arranged two-dimensionally on the surface of a substrate 109.

The image signals produced by the conversion performed by the photoelectric converter elements 108, control signals to control the photoelectric converter elements 108 and the like are transmitted and received via interconnections 104 provided in the interconnection layer 103. On a surface of the substrate 109 including a light receiving surface of the photoelectric converter elements 108, a reflection rate adjusted film 105 is formed. The reflection rate adjusted film 105 is constituted by a first portion 106 formed on at least a part of the light receiving surface of each photoelectric converter element 108 and a second portion 107 formed on other parts than the first portion 106.

The first portion 106 is provided in a one-to-one correspondence with each photoelectric converter element 108, and its reflection rate is adjusted to cause incident light to pass instead of reflecting the incident light. In addition, as detailed later, the first portion 106 is shifted for each corresponding photoelectric converter element 108, and the relative position thereof is strictly defined. The reflection rate of the second portion 107 is adjusted to reflect almost all the incident light. In this manner, in the reflection rate adjusted film 105, the reflection rate of the first portion 106 is adjusted to be smaller than the reflection rate of the second portion 107.

As described in further detail later, due to the operation of the reflection rate adjusted film 105 constituted by the first portion 106 and the second portion 107, parallax is caused in the subject luminous flux received by the photoelectric converter element 108. On the other hand, on the photoelectric converter element 108 not causing parallax, only the first portion 106 is formed to pass the entire incident luminous flux, and not having the second portion 107.

The color filter 102 is provided on the interconnection layer 103. Each of the color filters 102 is colored so as to transmit a particular wavelength range to a corresponding one of the photoelectric converter elements 108, and the color filters 102 are arranged in a one-to-one correspondence with the photoelectric converter elements 108. To output a color image, at least two different types of color filters that are different from each other need to be arranged. However, three or more different types of color filters may need to be arranged to produce a color image with higher quality. For example, red filters (R filters) to transmit the red wavelength range, green filters (G filters) to transmit the green wavelength range, and blue filters (B filters) to transmit the blue wavelength range may be arranged in a lattice pattern. The way how the filters are specifically arranged will be described later.

The microlenses 101 are provided on the color filters 102. The microlenses 101 are each a light collecting lens to guide more of the incident subject luminous flux to the corresponding photoelectric converter element 108. The microlenses 101 are provided in a one-to-one correspondence with the photoelectric converter elements 108. The optical axis of each microlens 101 is preferably shifted so that more of the subject luminous flux is guided to the corresponding photoelectric converter element 108 taking into consideration the relative positions between the pupil center of the image-capturing lens 20 and the corresponding photoelectric converter element 108. Furthermore, the position of each of the microlenses 101 as well as the position of the first portion 106 of the corresponding reflection rate adjusted film 105 may be adjusted to allow more of the particular subject luminous flux to be incident, which will be described later. Note that in the case of the image sensor having a favorable light collecting efficiency and a favorable photoelectric conversion efficiency, no microlens 101 may be provided.

Here, a pixel is defined as a single set constituted by one of the reflection rate adjusted films 105, one of the color filters 102, and one of the microlenses 101, which are provided in a one-to-one correspondence with one of the photoelectric converter elements 108. To be more specific, a pixel provided with a first portion 106 that causes parallax is referred to as a parallax pixel, and a pixel provided with a first portion 106 that does not cause parallax is referred to as a no-parallax pixel. For example, when the image sensor 100 has an effective pixel region of approximately 24 mm×16 mm, the number of pixels reaches as many as approximately 12 million.

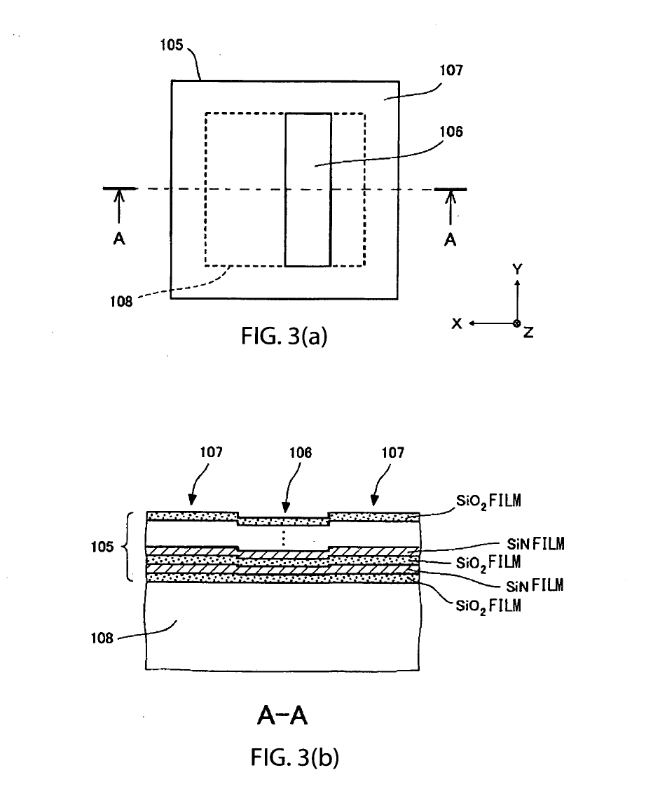

FIG. 3A and FIG. 3B explain a configuration of a reflection rate adjusted film 105 according to the present embodiment. FIG. 3A is a plan view of the reflection rate adjusted film 105 worth of one pixel. The first portion 106 passes a certain luminous flux out of the incident luminous fluxes, to guide the certain luminous flux towards a predetermined certain region on the light receiving surface of the corresponding photoelectric converter element 108. On the other hand, the second portion 107 prevents a luminous flux from being incident on any regions other than the certain region, on the light receiving surface of the photoelectric converter element 108. According to this configuration, parallax is caused on the subject luminous flux received by the photoelectric converter element 108.

FIG. 3B shows a cross section of an area in the vicinity of the first portion 106 of the reflection rate adjusted film 105. As shown in this drawing, the reflection rate adjusted film 105 is a multilayer film made by sequentially stacking a SiO₂ film and a SiN film. By differing the film thickness of each film in the first portion 106 and the film thickness of each film in the second portion 107, the reflection rate of the first portion 106 and the reflection rate of the second portion 107 are adjusted. For example, the film thickness of each film in the first portion 106 is defined so that the first portion 106 has a reflection rate of less than 10%, i.e., a transmission rate of 90% or more. In addition, for example, the film thickness of each film in the second portion 107 is defined so that the second portion 107 has a reflection rate of 99% or more, i.e., a transmission rate of less than 1%.

The following explains a method of forming the reflection rate adjusted film 105. First a SiO₂ film is formed on the surface of the substrate 109 in which the light receiving surface of the photoelectric converter element 108 is exposed. Then, photolithography and etching are performed so that the film thickness of the SiO₂ film on the first portion 106 is a predefined film thickness, and the film thickness of the SiO₂ film on the second portion 107 is a predefined film thickness. For example, when the film thickness of the SiO₂ film on the first portion 106 is set to be smaller than the film thickness of the SiO₂ film on the second portion 107, the SiO₂ film is formed on the surface of the substrate 109 to the film thickness on the second portion 107, and the portion of the first portion 106 is partially removed by photolithography and etching.

Next, a SiN film is formed on the SiO₂ film having been formed. Then, photolithography and etching are performed to have the film thickness of the SiN film on the first portion 106 being a predefined film thickness and the film thickness of the SiN film on the second portion 107 being a predefined film thickness. By sequentially repeating forming the SiO₂ film and forming the SiN film, the reflection rate adjusted film 105 is formed in which SiO₂ films and SiN films are sequentially stacked.

In this way, by forming the first portion 106 and the second portion 107 of the reflection rate adjusted film 105, on the light receiving surface of the photoelectric converter element 108, reception by the photoelectric converter element 108 of unnecessary luminous fluxes different from the luminous fluxes for causing parallax is efficiently prevented. In addition, by reducing the reflection rate of the first portion 106 as much as possible, the amount of light of the certain luminous flux received by the photoelectric converter element 108 can be larger than when there is no reflection rate adjusted film 105 formed.

Note in the above-described embodiment, the entire thickness of the first portion 106 is smaller than the entire thickness of the second portion 107. However, the present invention is not limited to this configuration. As long as the reflection rate of the first portion 106 and the reflection rate of the second portion 107 satisfy the defined values, the entire thickness of the first portion 106 may be equal to the entire thickness of the second portion 107 or larger than that.

In addition, in the above-described embodiment, the SiO₂ film and the SiN film ware used as films configuring the reflection rate adjusted film 105. However, the present invention is not limited to this configuration, and may alternatively use a film made of another material, such as a SiON film. In addition, the material of the film configuring the first portion 106 may differ from the material of the film configuring the second portion 107.

In addition, in the above-described embodiment, the reflection rate adjusted film 105 is configured by two portions having different refractive indexes from each other. However, the present invention is not limited to this configuration, and may be configured by three or more portions having refractive indexes from each other. In addition, the reflection rate adjusted film 105 may include a connecting portion connecting between the first portion 106 and the second portion 107, and having consecutively changing reflective indexes from the refractive index of the first portion 106 to the refractive index of the second portion 107.

In addition, in the above-described embodiment, as shown in FIG. 3A, the lengthwise direction of the first portion 106, i.e., the width in y axis direction, matches the width of the photoelectric converter element 108. However, the lengthwise width of the first portion 106 may be larger than the width of the photoelectric converter element 108. By making the lengthwise width of the first portion 106 to be larger than the width of the photoelectric converter element 108, reception of unexpected diffracted light for the photoelectric converter element 108 is prevented.

In the above-described embodiment, the structure of the reflection rate adjusted film 105 may be constant irrespective of the type of the color filter 102. In addition, the characteristic of the reflection rate adjusted film 105 may be different depending on the type of the color filter 102. Specifically, the film thickness of each film constituting the first portion 106 and the second portion 107 is adjusted for each type of color filters, so that each type of color filters 102 has a predefined reflection rate. For example, in the first portion 106 of the reflection rate adjusted film 105 corresponding to a G filter, the film thickness of each film is adjusted so that the transmittivity of light in a green wavelength region is favorable. In addition, in the second portion 107 of the reflection rate adjusted film 105 corresponding to a G filter, the film thickness of each film is adjusted so that the reflectivity of light in a green wavelength is favorable.

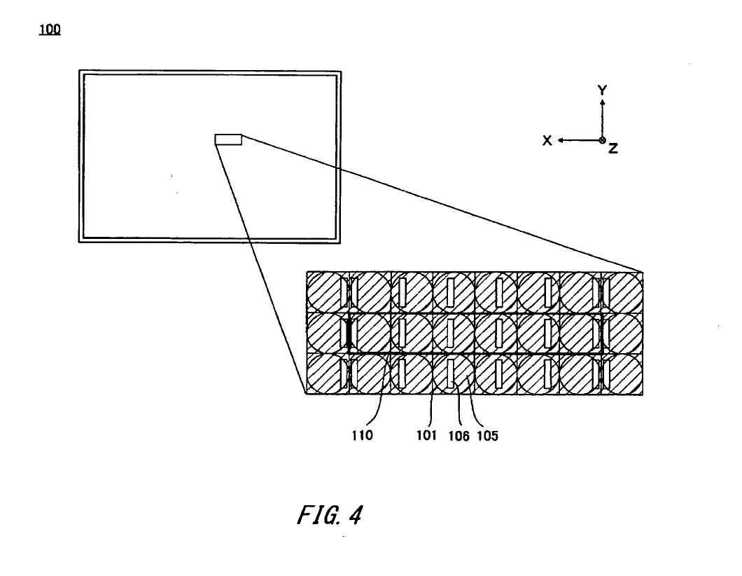

Next, the relation between the first portion 106 of the reflection rate adjusted film 105 and the resulting parallaxes is explained. FIG. 4 is an overview showing an enlarged view of a part of an image sensor 100. Here, so as to simplify the explanation, the colors of the color filters 102 are not mentioned till later. In the following explanation in which the colors of the color filters 102 are not mentioned, it can be interpreted as an image sensor resulting from collecting only parallax pixels having color filters 102 of a same color. Therefore, the following-explained repeating pattern may be considered as adjacent pixels in the same-colored color filter 102.

As shown in FIG. 3, the first portion 106 of the reflection rate adjusted film 105 is relatively shifted with respect to each pixel. In addition, the respective first portions 106 of the adjacent pixels are displaced to each other.

In the shown example, reflection rate adjusted films 105 in six types of pixel units are prepared in which the first portions 106 shifted in left and right directions each other are formed, and the second portions 107 are formed in portions different from where the first portions 106 are formed. In the whole image sensor 100, groups of photoelectric converter elements are arranged two dimensionally and periodically, in which in one group, six parallax pixels having reflection rate adjusted films 105 whose first portions 106 gradually shift from the left side towards the right side of the paper. Note that in the present embodiment, the alignment pattern of photoelectric converter element groups is referred to as a repeating pattern 110.

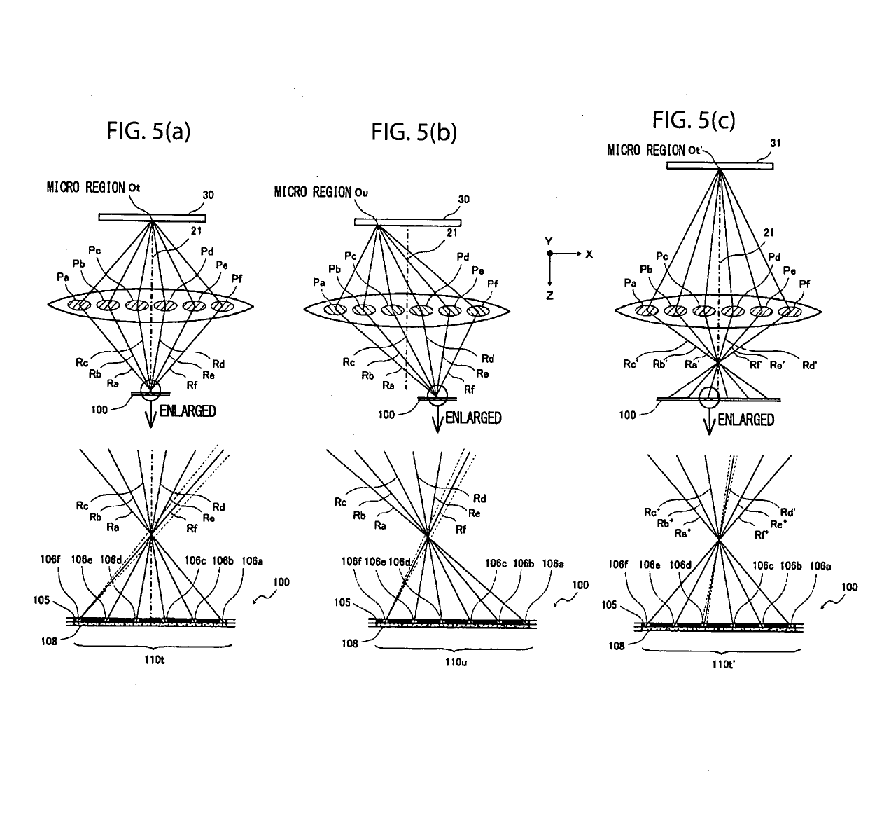

FIGS. 5A, 5B, and 5C are each a conceptual diagram illustrating the relation between parallax pixels and a subject. To be specific, FIG. 5A illustrates a photoelectric converter element group having a repeating pattern 1101 arranged at the center of the image sensor 100 through which the image-capturing optical axis 21 extends. FIG. 5B schematically illustrates a photoelectric converter element group having a repeating pattern 110u of the parallax pixels arranged in the peripheral portion of the image sensor 100. In FIGS. 5A and 5B, a subject 30 is positioned at a focus position relative to the image-capturing lens 20. FIG. 5C schematically illustrates the relation between the parallax pixels and the subject when a subject 31 at a non-focus position relative to the image-capturing lens 20 is captured, correspondingly to the relation shown in FIG. 5A.

The following first describes the relation between the parallax pixels and the subject when the image-capturing lens 20 captures the subject 30 at the focused state. The subject luminous flux is guided through the pupil of the image-capturing lens 20 to the image sensor 100. Here, six partial regions Pa to Pf are defined in the entire cross-sectional region through which the subject luminous flux transmits. For example, see the pixel, on the extreme left in the sheet of FIGS. 5A to 5C, of the photoelectric converter element groups having the repeating patterns 110t and 110u. The position of the first portion 106f of the reflection rate adjusted film 105 is defined so that only the subject luminous flux emitted from the partial region Pf reaches the photoelectric converter element 108 as seen from the enlarged view. Likewise, towards the pixel on the far right, the position of the first portion 106e is defined so as to correspond to the partial region Pe, the position of the first portion 106d is defined so as to correspond to the partial region Pd, the position of the first portion 106c is defined so as to correspond to the partial region Pc, the position of the first portion 106b is defined so as to correspond to the partial region Pb, and the position of the first portion 106a is defined so as to correspond to the partial region Pa.

Stated differently, for example, the gradient of the principal ray Rf of the subject luminous flux (partial luminous flux) emitted from the partial region Pf, which is defined by the relative positions of the partial region Pf and the leftmost pixel, may determine the position of the first portion 106f. When the photoelectric converter element 108 receives the subject luminous flux through the first portion 106f from the subject 30 at the focus position, the subject luminous flux forms an image on the photoelectric converter element 108 as indicated by the dotted line. Likewise, toward the rightmost pixel, the gradient of the principal ray Re determines the position of the first portion 106e, the gradient of the principal ray Rd determines the position of the first portion 106d, the gradient of the principal ray Rc determines the position of the first portion 106c, the gradient of the principal ray Rb determines the position of the first portion 106b, and the gradient of the principal ray Ra determines the position of the first portion 106a.

As shown in FIG. 5A, the luminous flux emitted from a micro region Ot of the subject 30 at the focus position, which coincides with the optical axis 21 on the subject 30, passes through the pupil of the image-capturing lens 20 and reaches the respective pixels of the photoelectric converter element group having the repeating pattern 110t. In other words, the pixels of the photoelectric converter element group having the repeating pattern 110t respectively receive the luminous flux emitted from the single micro region Ot through the six partial regions Pa to Pf. The micro region Ot has a certain spread that can accommodate the different positions of the respective pixels of the photoelectric converter element group having the repeating pattern 110t, but can be substantially approximated by substantially the same object point. Likewise, as shown in FIG. 5B, the luminous flux emitted from a micro region Ou of the subject 30 at the focus position, which is spaced away from the optical axis 21 on the subject 30, passes through the pupil of the image-capturing lens 20 to reach the respective pixels of the photoelectric converter element group having the repeating pattern 110u. In other words, the respective pixels of the photoelectric converter element group having the repeating pattern 110u respectively receive the luminous flux emitted from the single micro region Ou through the six partial regions Pa to Pf. Just as the micro region Ot, the micro region Ou has a certain spread that can accommodate the different positions of the respective pixels of the photoelectric converter element group having the repeating pattern 110u, but can be substantially approximated by substantially the same object point.

That is to say, as long as the subject 30 is at the focus position, the photoelectric converter element groups capture different micro regions depending on the positions of the repeating patterns 110 on the image sensor 100, and the respective pixels of each photoelectric converter element group capture the same micro region through the different partial regions. In the respective repeating patterns 110, the corresponding pixels receive subject luminous flux from the same partial region. To be specific, in the drawings, for example, the leftmost pixels of the repeating patterns 110t and 110u receive the partial luminous flux from the same partial region Pf.

Strictly speaking, the position of the first portion 106f of the leftmost pixel that receives the subject luminous flux from the partial region Pf in the repeating pattern 110t at the center through which the image-capturing optical axis 21 extends is different from the position of the first portion 106f of the leftmost pixel that receives the subject luminous flux from the partial region Pf in the repeating pattern 110u at the peripheral portion. From the perspective of the functions, however, these reflection rate adjusted film can be treated as the same type of reflection rate adjusted films in that they are both reflection rate adjusted films to receive the subject luminous flux from the partial region Pf. Accordingly, in the example shown in FIGS. 5A to 5C, it can be said that each of the parallax pixels arranged on the image sensor 100 has one of the six types of reflection rate adjusted films.

The following describes the relation between the parallax pixels and the subject when the image-capturing lens 20 captures the subject 31 at the non-focus state. In this case, the subject luminous flux from the subject 31 at the non-focus position also passes through the six partial regions Pa to Pf of the pupil of the image-capturing lens 20 to reach the image sensor 100. However, the subject luminous flux from the subject 31 at the non-focus position forms an image not on the photoelectric converter elements 108 but at a different position. For example, as shown in FIG. 5C, when the subject 31 is at a more distant position from the image sensor 100 than the subject 30 is, the subject luminous flux forms an image at a position closer to the subject 31 with respect to the photoelectric converter elements 108. On the other hand, when the subject 31 is at a position closer to the image sensor 100 than the subject 30 is, the subject luminous flux forms an image at a position on the opposite side of the subject 31 with respect to the photoelectric converter elements 108.

Accordingly, the subject luminous flux emitted from a micro region Ot′ of the subject 31 at the non-focus position reaches the corresponding pixels of different repeating patterns 110 depending on which of the six partial regions Pa to Pf the subject luminous flux passes through. For example, the subject luminous flux that has passed through the partial region Pd enters the photoelectric converter element 108 having the first portion 106d included in the repeating pattern 110t′ as a principal ray Rd′ as shown in the enlarged view of FIG. 5C. The subject luminous flux that has passed through the other partial regions may be emitted from the micro region Ot′, but does not enter the photoelectric converter elements 108 included in the repeating pattern 110f and enters the photoelectric converter elements 108 having the corresponding first portions 106 in different repeating patterns. In other words, the subject luminous fluxes that reach the respective photoelectric converter elements 108 constituting the repeating pattern 110t′ are subject luminous fluxes emitted from different micro regions of the subject 31. To be specific, the subject luminous flux having the principal ray Rd′ enters the photoelectric converter element 108 corresponding to the first portion 106d, and the subject luminous fluxes having the principal rays Ra⁺, Rb⁺, Rc⁺, Re⁺, Rf⁺, which are emitted from different micro regions of the subject 31, enter the photoelectric converter elements 108 corresponding to the other first portions 106. The same relation is also seen in the repeating pattern 110u arranged in the peripheral portion shown in FIG. 5B.

Here, when the image sensor 100 is seen as a whole, for example, a subject image A captured by the photoelectric converter element 108 corresponding to the first portion 106a and a subject image D captured by the photoelectric converter element 108 corresponding to the first portion 106d match with each other if they are images of the subject at the focus position, and do not match with each other if they are images of the subject at the non-focus position. The direction and amount of the non-match are determined by on which side the subject at the non-focus position is positioned with respect to the focus position, how much the subject at the non-focus position is shifted from the focus position, and the distance between the partial region Pa and the partial region Pd. Stated differently, the subject images A and D are parallax images causing parallax therebetween. This relation also applies to the other first portions 106, and six parallax images are formed corresponding to the first portions 106a to 106f.

Accordingly, a collection of outputs from the corresponding pixels in different ones of the repeating patterns 110 configured as described above produces a parallax image. To be more specific, the outputs from the pixels that have received the subject luminous flux emitted from a particular partial region of the six partial regions Pa to Pf form a parallax image.

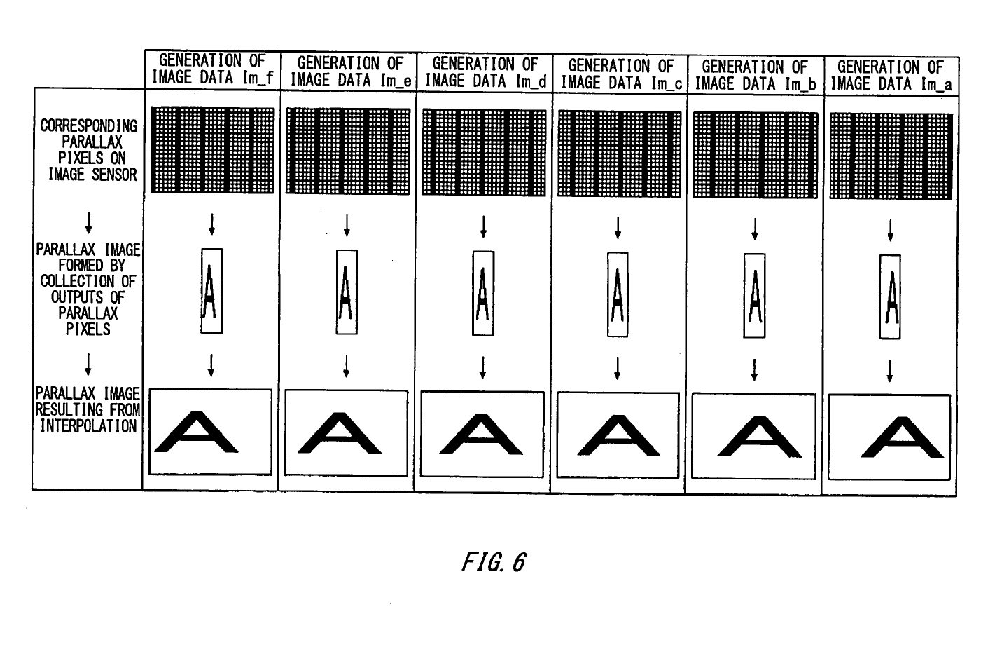

FIG. 6 is a conceptual diagram to illustrate an operation to produce a parallax image. FIG. 6 shows, from left to right, how parallax image data Im_f is produced by collecting the outputs from the parallax pixels corresponding to the first portions 106f, how parallax image data Im_e is produced from the outputs of the parallax pixels corresponding to the first portions 106e, how parallax image data Im_d is produced from the outputs of the parallax pixels corresponding to the first portions 106d, how parallax image data Im_c is produced from the outputs of the parallax pixels corresponding to the first portions 106c, how parallax image data Im_b is produced from the outputs of the parallax pixels corresponding to the first portions 106b, and how parallax pixel data Im_a is produced from the outputs from the parallax pixels corresponding to the first portions 106a. The following first describes how parallax image data Im_f is produced from the outputs from the parallax pixels corresponding to the first portions 106f.

The repeating patterns 110 each of which has a photoelectric converter element group constituted by a group of six parallax pixels are arranged side-by-side. Accordingly, on the hypothetical image sensor 100 excluding no-parallax pixels, the parallax pixels having the first portions 106f are found every six pixels in the horizontal direction and consecutively arranged in the vertical direction. These pixels receive subject luminous fluxes from different micro regions as described above. Therefore, parallax images can be obtained by collecting and arranging the outputs from theses parallax pixels.

However, the pixels of the image sensor 100 of the present embodiment are square pixels. Therefore, if the outputs are simply collected, the number of pixels in the horizontal direction is reduced to one-sixth and vertically long image data is produced. To address this issue, interpolation is performed to increase the number of pixels in the horizontal direction six times. In this manner, the parallax image data Im_f is produced as an image having the original aspect ratio. Note that, however, the horizontal resolution is lower than the vertical resolution since the parallax image data before the interpolation represents an image whose number of pixels in the horizontal direction is reduced to one-sixth. In other words, the number of pieces of parallax image data produced is inversely related to the improvement of the resolution. The interpolation applied in the present embodiment will be specifically described later.

In the similar manner, parallax image data Im_e to parallax image data Im_a are obtained. Stated differently, the digital camera 10 can produce parallax images from six different viewpoints with horizontal parallax.

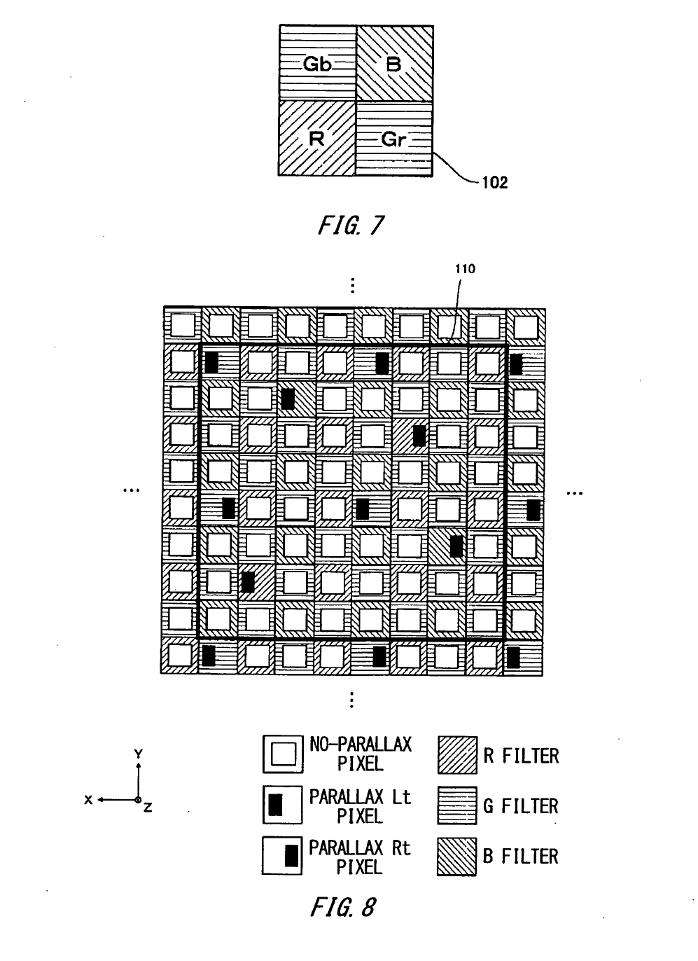

The following describes the color filters 102 and the parallax images. FIG. 7 illustrates a Bayer array. As shown in FIG. 7, G filters are assigned to the two pixels, i.e., the upper-left (Gb) and lower right (Gr) pixels, an R filter is assigned to one pixel, i.e., the lower left pixel, and a B filter is assigned to one pixel, i.e., an upper right pixel in the Bayer array.

Based on such an arrangement of the color filters 102, an enormous number of different repeating patterns 110 can be defined depending on to what colors of pixels the parallax and no-parallax pixels are allocated and the period in which parallax and no-parallax pixels are allocated. Collecting the outputs of the no-parallax pixels can produce no-parallax captured image data like an ordinary captured image. Accordingly, a high-resolution 2D image can be output by increasing the ratio of the no-parallax pixels relative to the parallax pixels. In this case, the ratio of the parallax pixels decreases relative to the no-parallax pixels and a 3D image formed by a plurality of parallax images exhibits lower image quality. On the other hand, if the ratio of the parallax pixels increases, the 3D image exhibits improved image quality. However, since the ratio of the no-parallax pixels decreases relative to the parallax pixels, a low-resolution 2D image is output. If the parallax pixels are allocated to all of the R, G and B pixels, the resulting color image data represents a 3D image having excellent color reproducibility and high quality.

Irrespective of whether the color image data represents a 2D or 3D image, the output color image data ideally has high resolution and quality. Here, the region of a 3D image for which an observer senses parallax when observing the 3D image is the non-focus region in which the identical subject images do not match, as understood from the cause of the parallax, which is described with reference to FIGS. 5A, 5B, and 5C. This means that, in the region of the image in which the observer senses parallax, fewer high-frequency components are present than in the focused image of the main subject. Considering this, the image data required to produce a 3D image does not need to have very high resolution in the region in which parallax is generated.

Regarding the focused region of the image, the corresponding image data is extracted from 2D image data. Regarding the non-focused region of the image, the corresponding image data is extracted from 3D image data. In this way, parallax image data can be produced by combining these pieces of image data for the focused and non-focused regions. Alternatively, high-resolution 2D image data is used as basic data and multiplied by the relative ratios of the 3D image data on the pixel-by-pixel basis. In this way, high-resolution parallax image data can be produced. When such image processing is employed, the number of the parallax pixels may be allowed to be smaller than the number of the no-parallax pixels in the image sensor 100. In other words, a 3D image having a relatively high resolution can be produced even if the number of the parallax pixels is relatively small.

In this case, to produce the 3D image in color, at least two different types of color filters may need to be arranged. In the present embodiment, however, three types of, i.e., R, G and B color filters are employed as in the Bayer array described with reference to FIG. 7 in order to further improve the image quality. To be specific, in the present embodiment where the number of parallax pixels is relatively small, the parallax pixels have all of the combinations of the different types of first portions 106 and the three types of, i.e., R, G and B color filters. Parallax Lt pixels having an first portion 106 shifted to the left from the center and parallax Rt pixels having an first portion 106 shifted to the right from the center are taken as an example. The parallax Lt pixels include a pixel having an R filter, a pixel having a G filter, and a pixel having a B filter, and the parallax Rt pixels include a pixel having an R filter, a pixel having a G filter, and a pixel having a B filter. Thus, the image sensor 100 has six different types of parallax pixels. Such an image sensor 100 outputs image data, which is used to form clear color parallax image data to realize a stereoscopic view. Note that, when two types of first portions 106 are combined with two types of color filters, the image sensor 100 has four types of parallax pixels.

The following describes a variation of the pixel arrangement. FIG. 8 illustrates the arrangement of pixels in a repeating pattern 110 relating to a first implementation. The repeating pattern 110 relating to the first implementation includes four Bayer arrays, each of which is formed by four pixels, arranged both in the vertical direction, which is the Y-axis direction, and in the horizontal direction, which is the X-axis direction, and is thus constituted by 64 pixels. This repeating pattern 110 has a pixel group of 64 pixels as a single unit, and a plurality of repeating patterns 110 are periodically arranged horizontally and vertically within the effective pixel region of the image sensor 100. Thus, the repeating pattern 110 bounded by the thick bold line in the drawing is the primitive lattice in the image sensor 100. Here, the pixels within the repeating pattern 110 are represented as P_{IJ}. For example, the leftmost and uppermost pixel is represented as P₁₁ and the rightmost and uppermost pixel is represented as P₈₁.

Each of the parallax pixels relating to the first implementation has one of the two types of reflection rate adjusted films 105, so that the parallax pixels are divided into the parallax Lt pixels having the first portions 106 shifted to the left from the center of the pixels and the parallax Rt pixels having the first portions 106 shifted to the right from the center of the pixels. As shown in the drawing, the parallax pixels are arranged in the following manner.

P₁₁ . . . parallax Lt pixel+G filter (=G(Lt))

P₅₁ . . . parallax Rt pixel+G filter (=G(Rt))

P₃₂ . . . parallax Lt pixel+B filter (=B(Lt))

P₆₃ . . . parallax Rt pixel+R filter (=R(Rt))

P₁₅ . . . parallax Rt pixel+G filter (=G(Rt))

P₅₅ . . . parallax Lt pixel+G filter (=G(Lt))

P₇₆ . . . parallax Rt pixel+B filter (=B(Rt))

P₂₇ . . . parallax Lt pixel+R filter (=R(Lt))

The other pixels are no-parallax pixels and include no-parallax pixels+R filter (=R(N)), no-parallax pixels+G filter (=G(N)), and no-parallax pixels+B filter (=B(N)).

As described above, the pixel arrangement preferably includes the parallax pixels having all of the combinations of the different types of first portions 106 and the different types of color filters within the primitive lattice of the pixel arrangement and has the parallax pixels randomly arranged together with the no-parallax pixels that are more than the parallax pixels. To be more specific, it is preferable, when the parallax and no-parallax pixels are counted according to each type of color filters, that the no-parallax pixels are still more than the parallax pixels. In the case of the first implementation, while G(N)=28, G(Lt)+G(Rt)=2+2=4, while R(N)=14, R(Lt)+R(Rt)=2, and while B(N)=14, B(Lt)+B(Rt)=2. In addition, as described above, considering the human spectral sensitivity characteristics, more parallax and no-parallax pixels having the G filter are arranged than the parallax and no-parallax pixels having the other types of color filters.

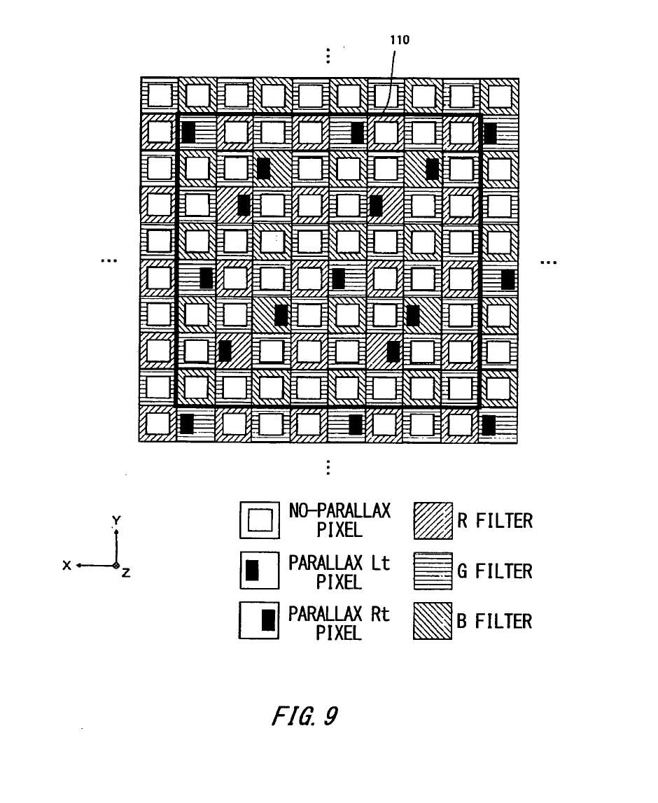

FIG. 9 illustrates how the pixels are arranged in a repeating pattern 110 relating to a second implementation. As in the first implementation, the repeating pattern 110 relating to the second implementation includes four Bayer arrays, each of which is formed by four pixels, both in the vertical direction, which is the Y-axis direction, and in the horizontal direction, which is the X-axis direction, and is thus constituted by 64 pixels. The repeating pattern 110 has a pixel group of 64 pixels as a single unit, and a plurality of repeating patterns 110 are periodically arranged horizontally and vertically within the effective pixel region of the image sensor 100. Thus, the repeating pattern 110 bounded by the thick bold line in the drawing is the primitive lattice in the image sensor 100.

In the second implementation, each of the parallax pixels has one of the two types of reflection rate adjusted film 105, so that the parallax pixels are divided into the parallax Lt pixels having the first portions 106 shifted to the left from the center of the pixels and the parallax Rt pixels having the first portions 106 shifted to the right from the center of the pixels. As shown in the drawing, the parallax pixels are arranged in the following manner.

P₁₁ . . . parallax Lt pixel+G filter (=G(Lt))

P₅₁ . . . parallax Rt pixel+G filter (=G(Rt))

P₃₂ . . . parallax Lt pixel+B filter (=B(Lt))

P₇₂ . . . parallax Rt pixel+B filter (=B(Rt))

P₂₃ . . . parallax Rt pixel+R filter (=R(Rt))

P₆₃ . . . parallax Lt pixel+R filter (=R(Lt))

P₁₅ . . . parallax Rt pixel+G filter (=G(Rt))

P₅₅ . . . parallax Lt pixel+G filter (=G(Lt))

P₃₆ . . . parallax Rt pixel+B filter (=B(Rt))

P₇₆ . . . parallax Lt pixel+B filter (=B(Lt))

P₂₇ . . . parallax Lt pixel+R filter (=R(Lt))

P₆₇ . . . parallax Rt pixel+R filter (=R(Rt))

The other pixels are no-parallax pixels and include no-parallax pixels+R filter (=R(N)), no-parallax pixels+G filter (=G(N)), and no-parallax pixels+B filter (=B(N)).

As described above, the pixel arrangement preferably includes the parallax pixels having all of the combinations of the different types of first portions 106 and the different types of color filters within the primitive lattice of the pixel arrangement and has the parallax pixels randomly arranged together with the no-parallax pixels that are more than the parallax pixels. To be more specific, it is preferable, when the parallax and no-parallax pixels are counted according to each type of color filters, that the no-parallax pixels are still more than the parallax pixels. In the case of the second implementation, while G(N)=28, G(Lt)+G(Rt)=2+2=4, while R(N)=12, R(Lt)+R(Rt)=4, and while B(N)=12, B(Lt)+B(Rt)=4.

Next, the concept of image process generating 2D image data and a plurality of pieces of parallax image data is also explained. As can be understood from an array of parallax pixels and no-parallax pixels in a repeating pattern 110, simple arrangement of the output of the image sensor 100 as it is to match its pixel array does not generate image data representing a certain image. Image data representing an image matching the characteristic can be formed by separating the pixel output of the image sensor 100 into each pixel group characterized to be the same, and then collecting them. For example, as already explained with reference to FIG. 6, by collecting the output of the parallax pixel according to each type of the first portion 106 would generate a plurality of pieces of parallax image data having parallax to each other. In this way, respective pieces of image data obtained by separating the parallax pixel output into each pixel group characterized to be the same and collecting them is referred to as plane data.

The image processor 205 receives RAW original image data in which the output values are arranged in the order of pixel array of the image sensor 100, and executes plane separation to separate the RAW original image data into a plurality of pieces of plane data. The following explains a generation process of each piece of plane data, with reference to an example of output from the image sensor 100 of the first embodiment example explained with reference to FIG. 8.

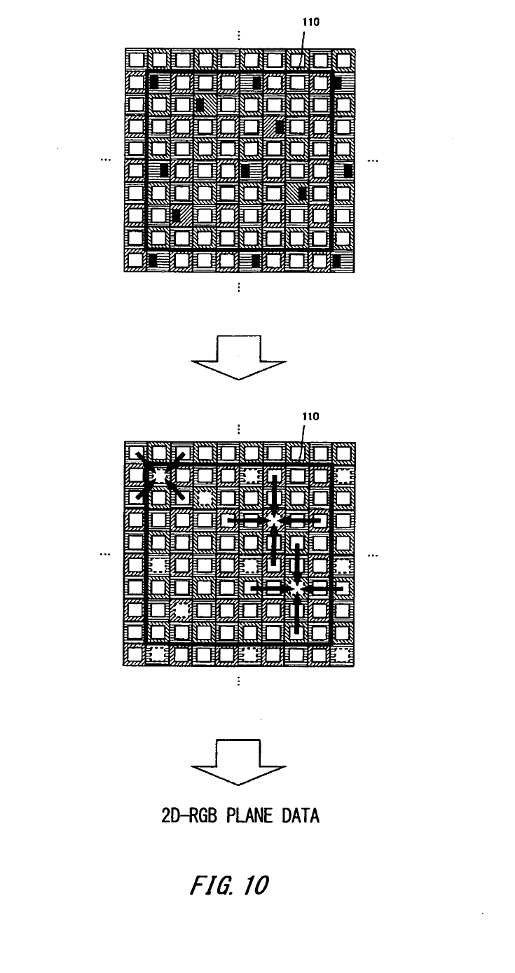

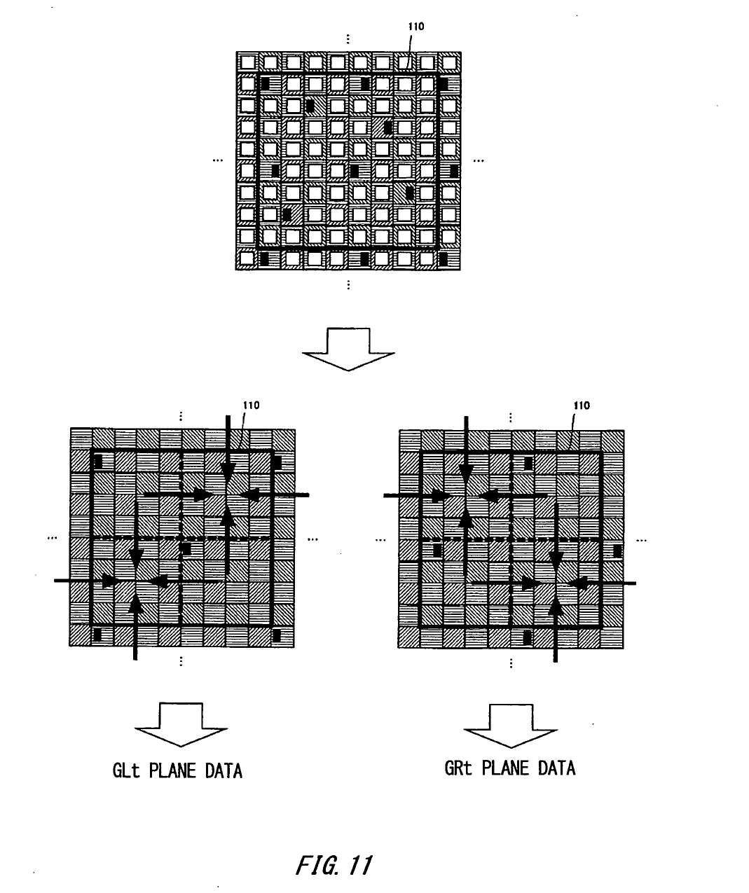

FIG. 10 illustrates, as an example, how to produce 2D-RGB plane data, which is 2D image data. The top drawing shows the outputs from the pixels in the single repeating pattern 110 and its surrounding pixels in the image sensor 100 in accordance with the pixel arrangement of the image sensor 100. Note that, in FIG. 10, the pixels are shown in accordance with the example of FIG. 8 so that the different types of pixels can be understood, but it is actually the output values corresponding to the pixels that are arranged.

To produce the 2D-RGB plane data, the image processor 205 first removes the pixel values of the parallax pixels and creates empty pixel positions. The pixel value for each empty pixel position is calculated by interpolation using the pixel values of the surrounding pixels having the color filters of the same type. For example, the pixel value for an empty pixel position P₁₁ is calculated by averaging the pixel values of the obliquely adjacent G-filter pixels P₋₁₋₁, P₂₋₁, P₋₁₂, P₂₂. Furthermore, for example, the pixel value for an empty pixel position P₆₃ is calculated by averaging the pixel values of the R-filter pixels P₄₃, P61, P₈₃, P₆₅ that are vertically and horizontally adjacent to the empty pixel position P₆₃ with one pixel position placed therebetween. Likewise, the pixel value for an empty pixel position P₇₆ is calculated by averaging the pixel values of the B-filter pixels P₅₆, P₇₄, P₉₆, P₇₈ that are vertically and horizontally adjacent to the empty pixel position P₇₆ with one pixel position placed therebetween.

The resulting 2D-RGB plane data obtained by the above-described interpolation is the same as the output from a normal image sensor having the Bayer array and can be subsequently subjected to various types of processing as 2D image data. The image processor 205 performs image processing in accordance with predetermined formats, for example, follows the JPEG standard or the like to produce still image data and follows the MPEG standard or the like to produce moving image data.

FIG. 11 illustrates, as an example, how to produce two pieces of G plane data, which are parallax image data. In other words, GLt plane data, which is left parallax image data, and GRt plane data, which is right parallax image data, are produced.

To produce the GLt plane data, the image processor 205 removes the pixel values, except for the pixel values of the G(Lt) pixels, from all of the output values of the image sensor 100 and creates empty pixel positions. As a result, two pixel values P₁₁ and P₅₅ are left in the repeating pattern 110. The repeating pattern 110 is vertically and horizontally divided into four portions. The pixel values of the 16 pixels in the upper left portion are represented by the output value at P_{H}, and the pixel values of the 16 pixels in the lower right portion are represented by the output value at P₅₅. The pixel value for the 16 pixels in the upper right portion and the pixel value for the 16 pixels in the lower left portion are interpolated by averaging the surrounding or vertically and horizontally adjacent representative values. In other words, the GLt plane data has one value per 16 pixels.

Likewise, to produce the GRt plane data, the image processor 205 removes the pixel values, except for the pixel values of the G(Rt) pixels, from all of the output values of the image sensor 100 and creates empty pixel positions. As a result, two pixel values P₅₁ and P₁₅ are left in the repeating pattern 110. The repeating pattern 110 is vertically and horizontally divided into four portions. The pixel values of the 16 pixels in the upper right portion are represented by the output value at P₅₁, and the pixel values of the 16 pixels in the lower left portion are represented by the output value at P₁₅. The pixel value for the 16 pixels in the upper left portion and the pixel value for the 16 pixels in the lower right portion are interpolated by averaging the surrounding or vertically and horizontally adjacent representative values. In other words, the GRt plane data has one value per 16 pixels.

In this manner, the GLt plane data and GRt plane data, which have lower resolution than the 2D-RGB plane data, can be produced.

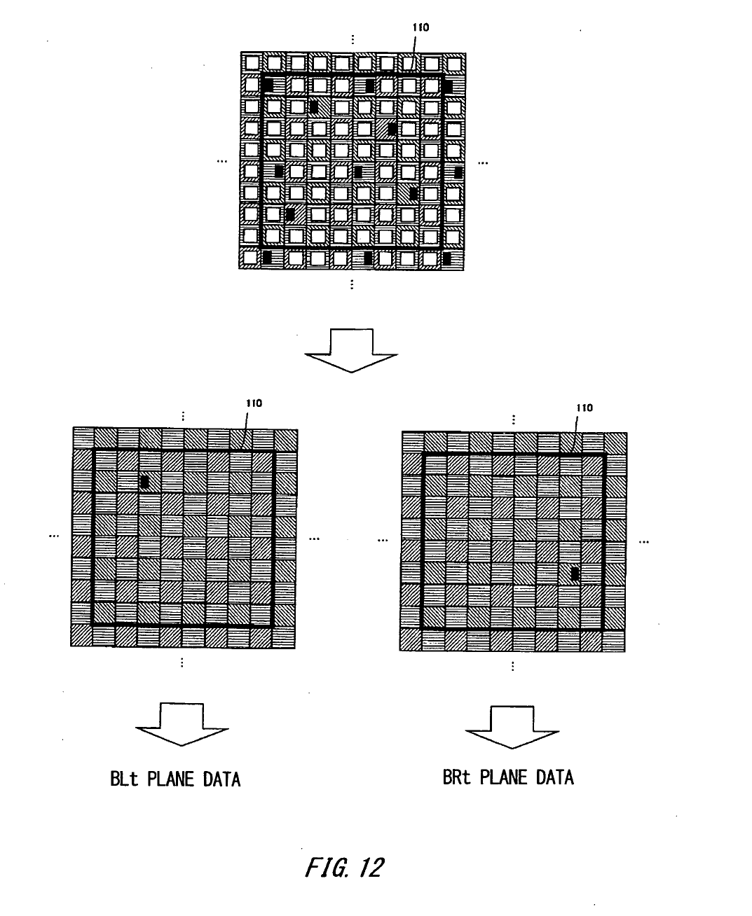

FIG. 12 illustrates, as an example, how to produce two pieces of B plane data, which are parallax image data. In other words, BLt plane data, which is left parallax image data, and BRt plane data, which is right parallax image data, are produced.

To produce the BLt plane data, the image processor 205 removes the pixel values, except for the pixel value of the B(Lt) pixel, from all of the output values of the image sensor 100 and creates empty pixel positions. As a result, a pixel value P₃₂ is left in the repeating pattern 110. This pixel value is used as the representative value of the 64 pixels of the repeating pattern 110.

Likewise, to produce the GRt plane data, the image processor 205 removes the pixel values, except for the pixel value of the B(Rt) pixel, from all of the output values of the image sensor 100 and creates empty pixel positions. As a result, a pixel value P₇₆ is left in the repeating pattern 110. This pixel value is used as the representative value of the 64 pixels of the repeating pattern 110.

In this manner, the BLt plane data and BRt plane data, which have lower resolution than the 2D-RGB plane data, can be produced. Here, the BLt plane data and BRt plane data have lower resolution than the GLt plane data and GRt plane data.

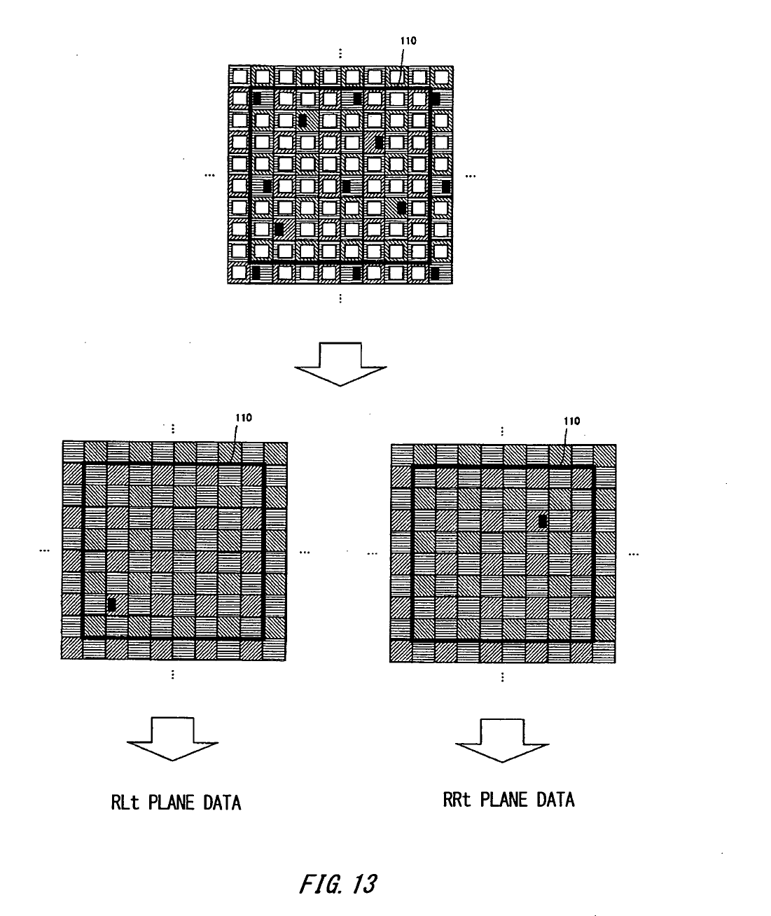

FIG. 13 illustrates, as an example, how to produce two pieces of R plane data, which are parallax image data. In other words, RLt plane data, which is left parallax image data, and RRt plane data, which is right parallax image data, are produced.

To produce the RLt plane data, the image processor 205 removes the pixel values, except for the pixel value of the R(Lt) pixel, from all of the output values of the image sensor 100 and creates empty pixel positions. As a result, a pixel value P₂₇ is left in the repeating pattern 110. This pixel value is used as the representative value of the 64 pixels of the repeating pattern 110.

Likewise, to produce the RRt plane data, the image processor 205 removes the pixel values, except for the pixel value of the R(Rt) pixel, from all of the output values of the image sensor 100 and creates empty pixel positions. As a result, a pixel value P₆₃ is left in the repeating pattern 110. This pixel value is used as the representative value of the 64 pixels of the repeating pattern 110.

In this manner, the RLt plane data and RRt plane data, which have lower resolution than the 2D-RGB plane data, can be produced. Here, the RLt plane data and RRt plane data have lower resolution than the GLt plane data and GRt plane data and substantially the same resolution as the BLt plane data and BRt plane data.

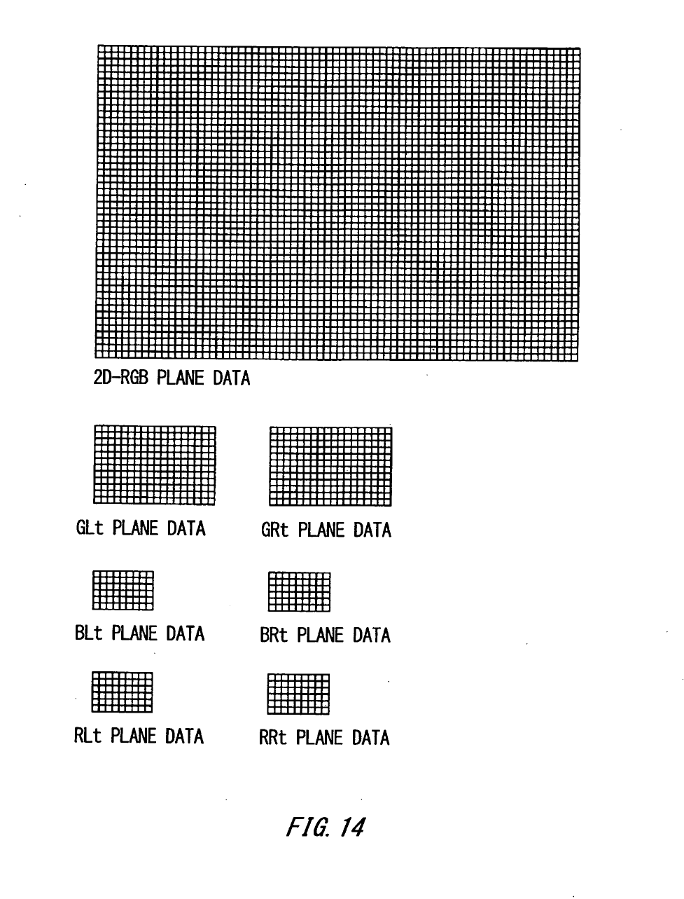

FIG. 14 is a conceptual view illustrating the relation between the resolutions of the respective planes. The 2D-RGB plane data has output values substantially the same as the number of effective pixels of the image sensor 100 since it has undergone interpolation. The GLt plane data and GRt plane data each have output values equal to 1/16 (¼×¼) of the number of pixels of the 2D-RGB plane data due to the interpolation. The BLt plane data, BRt plane data, RLt plane data and RRt plane data each have output values equal to 1/64 (=⅛×⅛) of the number of pixels of the 2D-RGB plane data.

Considering the differences between the resolutions of the above-described pieces of plane data, the high-resolution 2D image can be first output. For the focused region, the information of the 2D-RGB plane data is used, and for the non-focused region, parallax image data such as GLt plane data is used to perform synthesis processing or the like. In this way, 3D image which has sufficient resolution can be output.

Note that in the first embodiment example explained with reference to FIG. 8, G(N):R(N):B(N)=2:1:1, G(Lt):R(Lt):B(Lt)=1:1:1, and G(Rt):R(Rt):B(Rt)=1:1:1. In the second embodiment example explained with reference to FIG. 9, G(N):R(N):B(N)=7:3:3, G(Lt):R(Lt):B(Lt)=1:1:1, and G(Rt):R(Rt):B(Rt)=1:1:1. The allocation ratio of the no-parallax pixels with respect to the color filter, the allocation ratio of the parallax Lt pixel, and the allocation ratio of the parallax Rt pixel can be arbitrarily set. Not limited to the allocation ratio in the first embodiment example and the second embodiment example, it is also effective to set, to be the same, the allocation ratio of the no-parallax pixel, the allocation ratio of the parallax Lt pixel, and the allocation ratio of the parallax Rt pixel. For example, all of the respective allocation ratios can be set to 1:1:1, or to 2:1:1 so that the ratio of G is greater. By adjusting the allocation ratios in the stated manner, the correspondence between no-parallax image data and parallax image data can become easier.

Note that, while parallax images corresponding to the two viewpoints can be obtained by using the two different types of parallax pixels as in the first and second implementations, various numbers of types of parallax pixels can be used depending on the desired number of parallax images to output. Various repeating patterns 110 can be formed depending on the specifications, purposes or the like, irrespective of whether the number of viewpoints increases. In this case, to enable both output of 2D and output of 3D images to have a certain level of resolution, it is important that the primitive lattice of the image sensor 100 includes parallax pixels having all of the combinations of the different types of first portions 106 and the different types of color filters and that the no-parallax pixels are more than the parallax pixels.

In the above, the exemplary case is described in which the Bayer array is employed as the color filter arrangement. It goes without saying, however, other color filter arrangements can be used. Furthermore, in the above-described example, the three primary colors of red, green and blue are used for the color filters. However, four or more primary colors including emerald green may be used. In addition, red, green and blue can be replaced with three complementary colors of yellow, magenta and cyan.

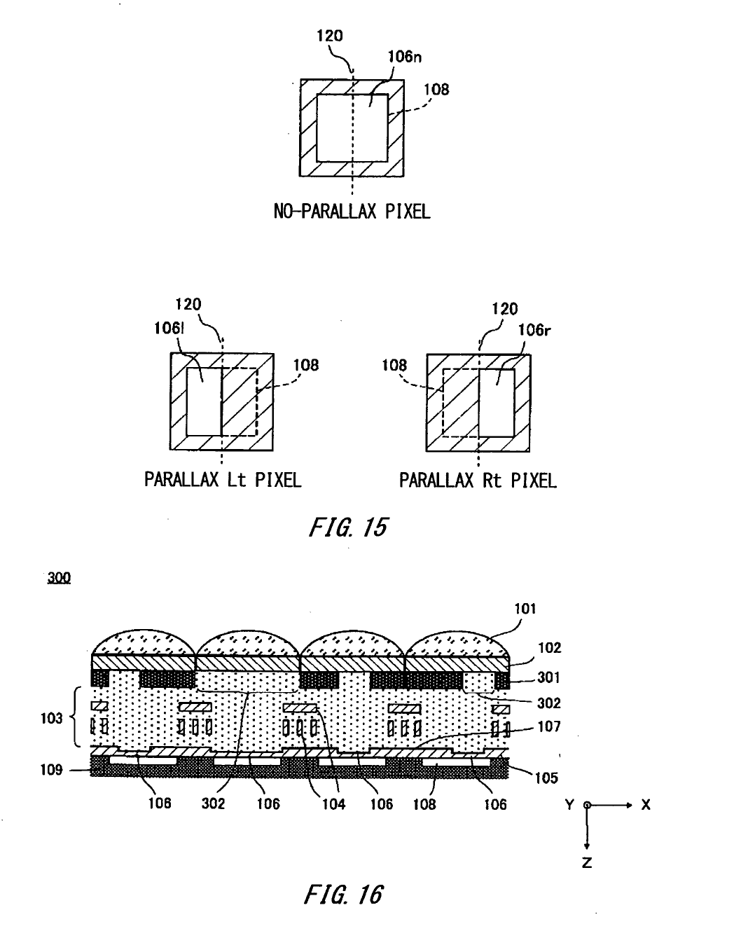

In the above-explained embodiment, the first portion 106 may be formed so that the area of the first portion 106 for the no-parallax pixel can correspond to a summation between the area of the first portion 106 for the parallax Lt pixel and the area of the first portion 106 for the parallax Rt pixel. FIG. 15 explains a shape of a first portion 106. The first portion 106n of the no-parallax pixel is formed to have a same size as the photoelectric converter element 108. The first portion 1061 of the parallax Lt pixel is formed to have a same size as a left half of the photoelectric converter element 108. The first portion 106r of the parallax Rt pixel is formed to have a same size as a right half of the photoelectric converter element 108.

Therefore, the shape of the first portion 1061 of the parallax Lt pixel and the shape of the first portion 106r of the parallax Rt pixel are respectively the same as the shape of the respective portion resulting from dividing the shape of the first portion 106n of the no-parallax pixel by the center line 120. By forming the first portion 106 of each pixel in this way, the area of the first portion 106n of the no-parallax pixel becomes a summation between the area of the first portion 1061 of the parallax Lt pixel and the area of the first portion 106r of the parallax Rt pixel.

Here, each of the first portion 106n of the no-parallax pixel, the first portion 1061 of the parallax Lt pixel, and the first portion 106r of the parallax Rt pixel has a function as an aperture diaphragm. Therefore, the amount of out of focus of the no-parallax pixel having the first portion 106n having an area twice as the first portion 1061 (first portion 106r) will be the same level as the summation of the amounts of out of focus of the parallax Lt pixel and the parallax Rt pixel. By defining the relation of the amount of out of focus between the parallax pixel and the no-parallax pixel in this manner, interpolation of the no-parallax pixel using the pixel value of the parallax pixel and interpolation of the pixel value of the parallax pixel using the pixel value of the no-parallax pixel become easy.

In the above-stated embodiment, the output of the AF sensor 211 is used for the determination of the focused region. However, the determination can also be done by comparing the output values of the parallax image data. For example, the controller 201 determines that it is the focused state when the pixel values of the corresponding pixels of the GLt plane data and the GRt plane data are the same as each other, and determines that the region including the pixel is the focused region.

In addition, the above-described parallax pixel can be aligned as a phase detection pixel in the plurality of focus detection regions set to the effective pixel region of the image sensor 100. Specifically, the parallax Rt pixels may be aligned one dimensionally in the left and right direction in the focus detection region, as the phase detection pixels in the left and right direction. Above or below the parallax Rt pixels, the parallax Lt pixels are aligned one dimensionally in the left and right direction in the focus detection region, as the phase detection pixels in the left and right direction. The controller 201 executes a correlation operation using output of the parallax Rt pixel and the output of the parallax Lt pixel in the focus detection region, to perform focus determination. In a portion other than the phase detection pixel in the effective region of the image sensor 100, the parallax pixel and the no-parallax pixel can be mixed and aligned as stated above. Or, only no-parallax pixels may be aligned to generate 2D image data without any parallax.

Note that the parallax Rt pixel and the parallax Lt pixel may be alternately aligned one dimensionally in the left and right direction in the focus detection region. In addition, together with or instead of the phase detection pixels in the left and right direction, the upper parallax pixel in which the first portion 106 is shifted in the upper direction from the center and the lower parallax pixel in which the first portion 106 is shifted in the lower direction from the center may be used as a phase detection pixel in the upper and lower direction.

Note that so as to output a phase difference signal having high accuracy, the phase detection pixel may not be provided with a color filter 102. In addition, not all the focus detection region may be constituted by phase detection pixels. It is sufficient that the phase detection pixels sufficient to perform focus determination favorably are aligned in the focus detection region.

In the above-described embodiment, the image sensor 100 having the structure shown in FIG. 2 is used. However, the structure of the image sensor is not limited to the stated structure. FIG. 16 schematically shows a cross section of an image sensor 300 according to a first modification example. The image sensor 300 is such that an aperture mask 301 is provided to the above-described image sensor 100. The members of the image sensor 300 that are the same as those of the image sensor 100 are assigned the same reference numerals, and the explanation of the function thereof is omitted in the following.

The aperture mask 301 is provided to contact the interconnection layer 103. On the aperture mask 301, a color filter 102 is provided. The aperture 302 of the aperture mask 301 is provided in a one-to-one correspondence with each photoelectric converter element 108. The aperture 302 is shifted for each corresponding photoelectric converter element 108, and the relative position thereof is strictly defined. In addition, the aperture 302 is provided in a one-to-one correspondence with each first portion 106. The aperture 302 passes a certain luminous flux out of the incident luminous flux, and guides the certain luminous flux to a corresponding first portion 106. In this way, in the first modification example, the operation of the first portion 106 and the aperture 302 causes a parallax in the subject luminous flux received by the photoelectric converter element 108. On the other hand, no aperture mask 301 is provided over the photoelectric converter element 108 that does not cause any parallax. Stated differently, an aperture mask 301 that includes an aperture 302 that does not block the subject luminous flux incident to the corresponding photoelectric converter element 108, i.e., that permits all the incident luminous flux to pass, is provided.

In the first modification example, the two members, i.e., the reflection rate adjusted film 105 and the aperture mask 301, are used as a light-blocking member, which enhances the light-blocking efficiency of unnecessary luminous fluxes. Note that because the aperture mask 301 can block unnecessary luminous flux to some extent, the reflection rate of the second portion 107 of the reflection rate adjusted film 105 in the first modification example can be smaller than in the above-explained embodiment that is without any aperture mask 301. In an example, the reflection rate of the second portion 107 is defined to about 50%.

In the first modification example, the aperture mask 301 may be aligned independently and separately corresponding to each photoelectric converter element 108. Alternatively, the aperture mask 301 may be collectively formed to the plurality of photoelectric converter elements 108, in the similar manner to the manufacturing process of the color filter 102. In addition, by enabling the aperture 302 of the aperture mask 301 to have color components, the color filter 102 and the aperture mask 301 can be integrally formed.

In addition, in the first modification example, the aperture mask 301 and the interconnection 104 are provided as different entities. However, the function of the aperture mask 301 in the parallax pixel can be performed by the interconnection 104. That is, the interconnection 104 may be used to shape the defined aperture form, and this aperture form may be used to restrict the incident luminous flux thereby guiding only a certain partial luminous flux towards the first portion 106. In this case, the interconnection 104 shaping the aperture form is preferably closest to the photoelectric converter element 108 in the interconnection layer 103.

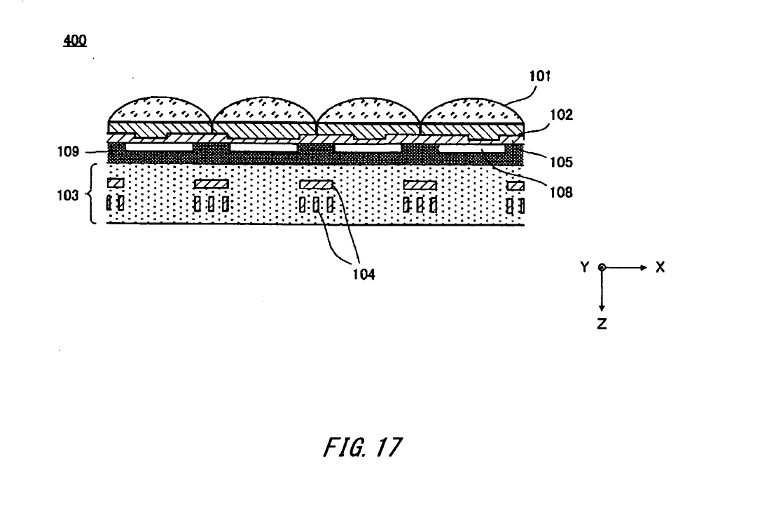

FIG. 17 schematically shows a cross section of an image sensor 400 according to a second modification example. The image sensor 400 is a backside illumination image sensor in which the interconnection layer 103 is provided on a side of the substrate 109 opposite to a side to which the photoelectric converter element 108 is provided. Note that the members of the image sensor 400 are the same as those of the image sensor 100, and so the explanation of the function thereof is omitted in the following.

As shown in FIG. 17, the color filter 102 is provided on the reflection rate adjusted film 105. In addition, the interconnection layer 103 is provided on a surface opposite to the surface of the substrate 109 on which the light receiving surface of the photoelectric converter element 108 is exposed. In this way, the reflection rate adjusted film according to the present embodiment described above can also be applied to a backside illumination image sensor.

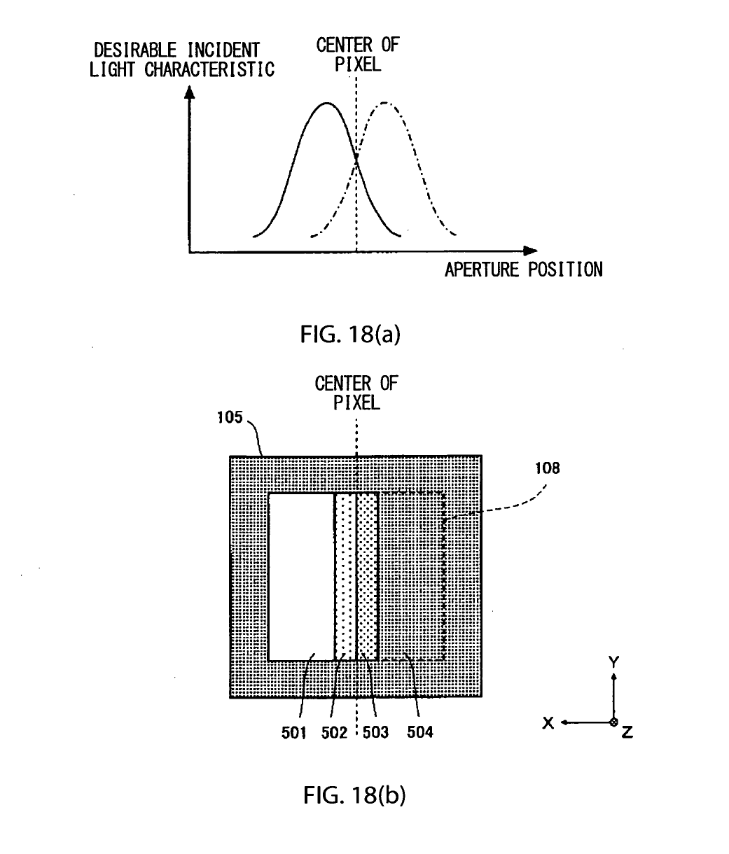

Next, a variation of the configuration of the reflection rate adjusted film explained with reference to FIG. 3 is explained. FIG. 18 explains a configuration of a reflection rate adjusted film 105 adjusted to the incident light characteristic.

In FIG. 18A, the lateral axis shows a position of an aperture with respect to the x axis direction (the left and right direction on the paper of the drawing) of the photoelectric converter element 108, and the longitudinal axis shows an optical intensity distribution as an ideal incident light characteristic. Note that the optical intensity distribution of the parallax Lt pixel is shown as a solid line, and the optical intensity distribution of the parallax Rt pixel is shown by an alternate long and short dash line. So as to assist the realization of such an optical intensity distribution, the region of the photoelectric converter element 108 is divided in a plurality of portions, and each portion is differed in transmission rate.

FIG. 18B explains a configuration of a reflection rate adjusted film 105 in a third embodiment example. Just as FIG. 3A, this is a plan view of the reflection rate adjusted film 105 worth of one pixel. A first portion 501 is a region occupying left ¾ of the left half of the photoelectric converter element 108, and its transmission rate is adjusted to 100%. The second portion 502 is a region occupying right ¼ of the left half of the photoelectric converter element 108, and its transmission rate is adjusted to 50%. The third portion 503 is a region occupying left ¼ of the right half of the photoelectric converter element 108, and its transmission rate is adjusted to 10%, and the fourth portion 504 is the other region, and its transmission rate is adjusted to 0%, i.e., is adjusted to block the incident light. In this way, the region of one pixel is divided, and the transmission rate of the incident light is differed according to each portion, thereby enabling to obtain an incident light characteristic closer to the ideal state.

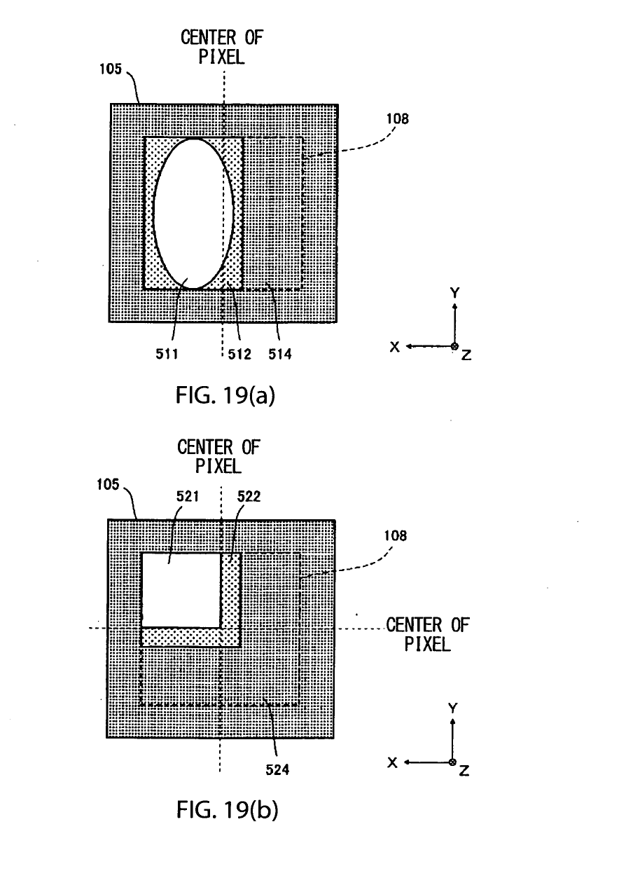

FIG. 19A and FIG. 19B explain a configuration of a reflection rate adjusted film 105 according to a further different variation. One pixel not only can be divided in x axis direction (left and right direction of the paper of the drawing) of the photoelectric converter element 108, but also can be divided two dimensionally including y axis direction (upper and lower direction of the paper of the drawing).

FIG. 19A explains a configuration of the reflection rate adjusted film 105 according to a fourth modification example. Just as FIG. 3A, this is a plan view of the reflection rate adjusted film 105 worth of one pixel. A first portion 511 is an ellipsoidal region included in the left ⅝ region of the photoelectric converter element 108, and its transmission rate is adjusted to 100%. The long axis of the ellipse is the width of the photoelectric converter element 108 in y axis direction. In addition, a part of the ellipsoidal region enters the right half region, passing the central axis of the pixel. The second portion 512 is a region corresponding to the left ⅝ region of the photoelectric converter element 108 excluding the first region, and its transmission rate is adjusted to 15%. The third portion 514 is the other region, and its transmission rate is adjusted to 0%, i.e., adjusted to block the incident light. If division is pursued in this way, an incident light characteristic closer to the ideal state can be obtained also in the y axis direction.

FIG. 19B explains a configuration of the reflection rate adjusted film 105 according to a fifth modification example. Just as FIG. 3A, this is a plan view of the reflection rate adjusted film 105 worth of one pixel. The first portion 521 is a region occupying the upper left ¼ of the photoelectric converter element 108, and its transmission rate is adjusted to 100%. The second portion 522 is a border region in contact with the two sides of the first portion 521 that are close to the center of the photoelectric converter element 108, and its transmission rate is adjusted to 30%. The third portion 524 is the other region, and its transmission rate is adjusted to 0%, i.e., adjusted to block the incident light. Such division can also be applied to parallax pixels also giving parallax in the y axis direction.

With reference to FIG. 3B, the reflection rate adjusted film 105 was explained to be a multilayer film made by sequentially stacking a SiO₂ film and a SiN film. However, not limited to this, many variations can be considered for the film composition. For example, a SiON film can be used instead of a SiO₂ film, a Ta₂O₅ film, a MgF film, and a SiON film can be used instead of a SiN film. Furthermore, it is possible to make the multilayer film by adding a SiON film between the SiO₂ film and the SiN film, to have three types of film compositions.

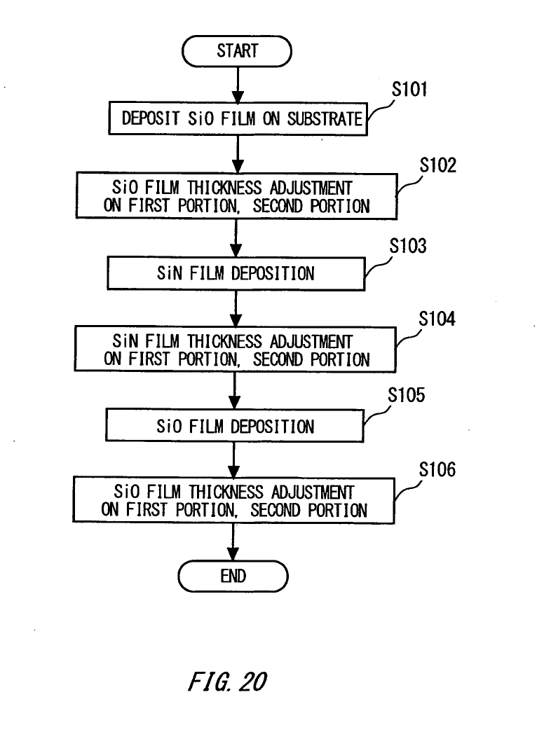

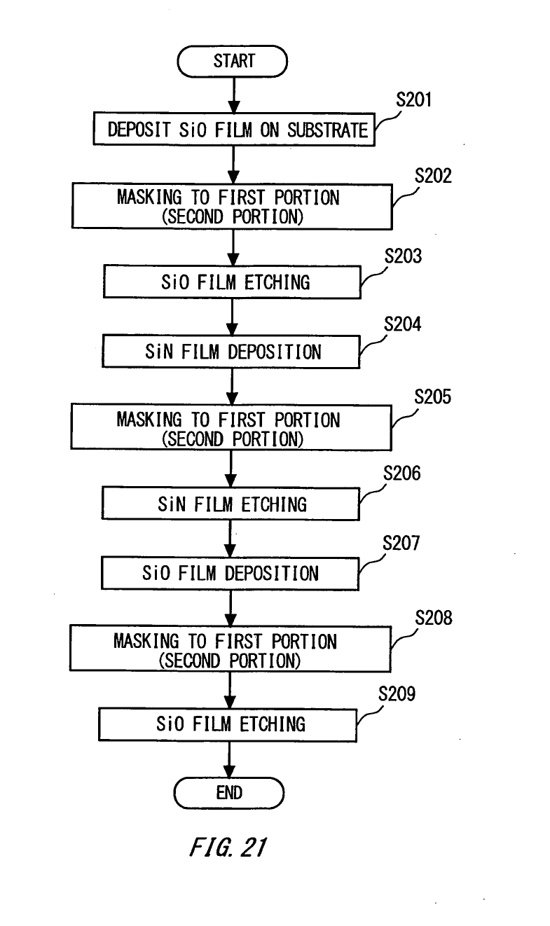

The following explains a manufacturing process of a film structure having a film composition of three layers, i.e., a SiO₂ film, a SiN film, and a SiO₂ film. FIG. 20 shows a process flow according to a first manufacturing process. The flow starts from the state in which the substrate on which the photoelectric converter element is formed is fixed.

In Step S101, a SiO₂ film is deposited on a substrate. Moving onto Step S102, in the deposited SiO₂ film, the film thicknesses of the first portion defined as a transmitting region and the second portion defined as a light-blocking region are adjusted.

Next, in Step S103, a SiN film is deposited on the SiO₂ film of which film thickness has been adjusted. Moving onto Step S104, in the deposited SiN film, the film thicknesses of the first portion and the second portion are adjusted. In addition, in Step S105, a SiO₂ film is deposited on the SiN film of which the film thickness has been adjusted. Moving onto Step S106, in the deposited SiO₂ film, the film thicknesses of the first portion and the second portion are adjusted, to end the series of processes. To add more layers, deposition of a SiN film, a SiO₂ film, and their film thickness adjustment can be repeated.

FIG. 21 shows a process flow according to the second manufacturing process, regarding the manufacturing process of the film structure having a deposition composition of three layers of a SiO₂ film, a SiN film, and a SiO₂ film. The flow starts from the state in which the substrate on which the photoelectric converter element is formed is fixed.

In step S201, a SiO₂ film is deposited on the substrate. Moving onto Step S202, masking is performed to the deposited SiO₂ film, to divide a first portion defined as a transmitting region from a second portion defined as a light-blocking region. Moving onto Step S203, etching is performed to the SiO₂ film. The region not provided with masking is etched away, to adjust the film thickness.

Next in Step S204, a SiN film is deposited on the SiO₂ film of which the film thickness has been adjusted. Moving onto Step S205, masking is performed to the deposited SiN film, to divide the first portion from the second portion. Moving onto Step S206, etching is performed to the SiN film. The region not provided with masking is etched away, to adjust the film thickness

Next in Step S207, a SiO₂ film is deposited on the SiN film of which the film thickness has been adjusted. Moving onto Step S208, masking is performed to the deposited SiO₂ film, to divide the first portion from the second portion. Moving onto Step S209, etching is performed to the SiO₂ film. The region not provided with masking is etched away, to adjust the film thickness, and the series of processes ends. To add more layers, deposition of a SiN film, a SiO₂ film, masking, and etching may be repeated. Note that the masked region of the SiO₂ film and the masked region of the SiN film may be the same region, or they may alternate. If the masked regions are to alternate, the first portion in the SiO₂ film is masked, and the second portion in the SiN film is masked, for example.

In addition, the region other than the photoelectric converter element 108 may be left remaining. In this region, if the film is left without being etched away, a cross-talk prevention effect may be obtained in some cases.

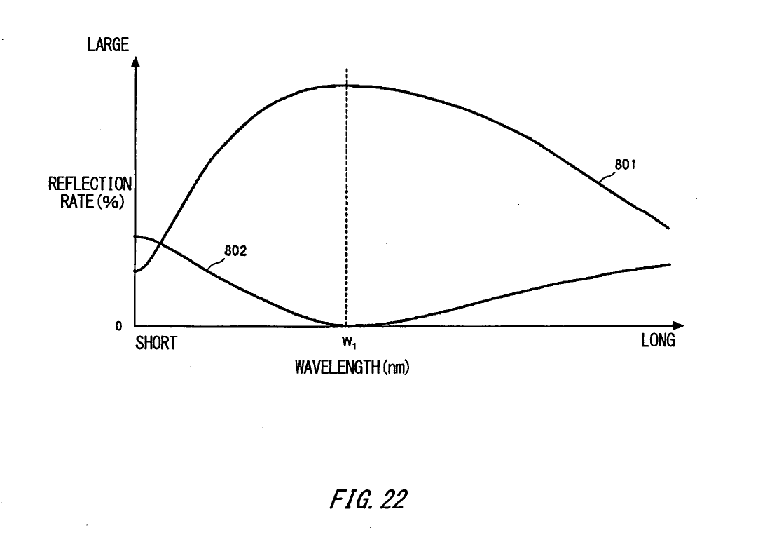

Next, a simulation result of the reflection rate of a concrete film composition with respect to the incident wavelength is explained. FIG. 22 shows a simulation result of a reflection rate of each film composition with respect to an incident wavelength of a visible light region. In this drawing, the lengthwise axis represents a wavelength (nm) of incident light corresponding to a visible light region, and the longitudinal axis represents reflection rate (%).

The curve 801 represents a reflection rate characteristic of a configuration of a film A deposited under a reflection rate increasing condition. An example of the reflection rate increasing condition is such that, on a Si substrate, four layers of a SiO₂ film having a film thickness of t₁nm, a SiN film having a film thickness of t₂nm, a SiO₂ film having a film thickness of t₃nm, and a SiN film having a film thickness of t₄nm are stacked. The reflection rate of this stacked film gradually increases from a short wavelength side, and gradually decreases towards a longer wavelength side, with the apex being around W₁nm.

The curve 802 represents a reflection rate characteristic of a configuration of a film B deposited under a reflection rate decreasing condition. An example of the reflection rate decreasing condition is such that, on a Si substrate, four layers of a SiO₂ film having a film thickness of t₅nm, a SiN film having a film thickness of t₆nm, a SiO₂ film having a film thickness of t₇nm, and a SiN film having a film thickness of t₈nm, having a film-thickness combination different from the film-thickness combination of the film A, are stacked. The reflection rate of the stacked film gradually decreases from a short wavelength side, reaches 0 around W₁nm, and gradually increases towards a longer wavelength side.

As the above result shows, it is clear that completely reversed characteristics are obtained by changing the film thicknesses alternately even when the deposition composition is the same, such as exemplified by the reflection characteristic of the film A and the reflection characteristic of the film B. it is needless to say that more varieties of reflection rates can be obtained by further changing the number of stacked layer, film thicknesses, and so on.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

What is claimed is:

1. An image sensor comprising:
photoelectric converter elements aligned two dimensionally, and photoelectric converting incident light into an electric signal; and
reflection rate adjusted films, each of which is formed on a light receiving surface of a photoelectric converter element of at least a part of the photoelectric converter elements and at least includes a first portion having a first reflection rate and a second portion having a second reflection rate different from the first reflection rate.

2. The image sensor according to claim 1, wherein
the first reflection rate is smaller than the second reflection rate, and
the first portions of the reflection rate adjusted films respectively formed on the light receiving surfaces of at least two of n adjacent photoelectric converter elements out of the photoelectric converter elements are arranged to pass luminous fluxes from different partial regions from each other of a cross-sectional region of the incident light, where n is an integer equal to or greater than 2.

3. The image sensor according to claim 2, wherein
groups of photoelectric converter elements, each made up of the n adjacent photoelectric converter elements, are aligned successively.

4. The image sensor according to claim 1, comprising
color filters positioned closer to a subject than the reflection rate adjusted films are and provided in a one-to-one correspondence with the photoelectric converter elements.

5. The image sensor according to claim 4, wherein
characteristics of the reflection rate adjusted films differ according to types of the color filters.

6. The image sensor according to claim 1, comprising
aperture masks positioned closer to a subject than the reflection rate adjusted films are and provided in a one-to-one correspondence with the photoelectric converter elements.

7. The image sensor according to claim 1, comprising:
a substrate, one of two opposing surfaces thereof being provided with the photoelectric converter elements; and
an interconnection layer formed on the other of the two opposing surfaces of the substrate.

8. An imaging device, comprising:
the image sensor according to claim 1; and
an image processor that generates, from an output of the image sensor, a plurality of pieces of parallax image data having parallax to each other and 2D no-parallax image data.

9. A method of manufacturing reflection rate adjusted films formed on light receiving surfaces of photoelectric converter elements aligned two dimensionally and photoelectric converting incident light into an electric signal, the method comprising:
depositing a first film on a substrate on which the photoelectric converter elements are formed;
adjusting a film thickness of the first film so that a first portion and a second portion resulting from dividing a light receiving surface of each of the photoelectric converter elements have film thicknesses different from each other;
depositing a second film different from the first film, on the first film; and
adjusting a film thickness of the second film so that the first portion and the second portion have film thicknesses different from each other.

10. A method of manufacturing reflection rate adjusted films formed on light receiving surfaces of photoelectric converter elements aligned two dimensionally and photoelectric converting incident light into an electric signal, the method comprising:
depositing a first film on a substrate on which the photoelectric converter elements are formed;
masking a first portion, out of the first portion and a second portion resulting from dividing a light receiving surface of each of the photoelectric converter elements;
etching the first film;
depositing a second film different from the first film, on the first film;
masking one of the first portion and the second portion; and
etching the second film.

11. The method of manufacturing reflection rate adjusted films according to claim 9, wherein
the first film has a composition selected from SiO₂ and SiON, and the second film has a composition selected from SiN, Ta₂O₅, MgF, and SiON.
